(19) United States
(12) Patent Application Publication
(10) Pub. No.: US 2024/0206612 A1
(43) Pub. Date: Jun. 27, 2024

(54) HAIRCARE APPLIANCE

(71) Applicant: Dyson Technology Limited, Wiltshire (GB)

(72) Inventors: Yuen Kee LEOW, Singapore (SG); Li NIU, Singapore (SG); Stephen John WOOLAGHAN, Swindon (GB); Kishan Mayur AMRATIA, Bristol (GB); Stephen BERRY, Swindon (GB); Michael James WAITE, Cirencester (GB); Andrew John Dennis SPILLMAN, Bristol (GB); Neil WAREHAM, Gloucester (GB); Robert STREETER, Singapore (SG)

(73) Assignee: Dyson Technology Limited, Wiltshire (GB)

(21) Appl. No.: 18/288,567

(22) PCT Filed: Apr. 19, 2022
(86) PCT No.: PCT/GB2022/050980

§ 371 Date: Oct. 26, 2023

(30) Foreign Application Priority Data
Apr. 30, 2021 (GB) 2106251.8

(51) Int. Cl. A45D 20/12; H03K 17/56

(52) U.S. Cl. CPC A45D 20/12; H03K 17/56

(57) ABSTRACT

A haircare device includes at least one power semiconductor switch coupled to drive, in use, a heater. A temperature sensor disposed for sensing a temperature of the at least one power semiconductor switch and outputting a temperature signal indicative of the sensed temperature. A controller is configured to determine whether the temperature signal is indicative of a temperature of the one or more power semiconductor switch exceeding a threshold. When the temperature signal is indicative of the temperature of the one or more power semiconductor switch exceeding the threshold, a power output of the at least one power semiconductor switch is turned off or reduced.

### FIELD OF INVENTION

The present invention relates to a haircare appliance.

### BACKGROUND

Haircare appliances are generally used to treat or style hair, and some haircare appliances may treat or style hair using airflow along with heat. Such haircare appliances are typically held by a user and moved relative to the hair to obtain desired treatment or styling.

### SUMMARY OF INVENTION

According to a first aspect, there is provided a haircare appliance comprising: a heater; at least one power semiconductor switch coupled to drive, in use, the heater; a temperature sensor disposed for sensing a temperature of the at least one power semiconductor switch and outputting a temperature signal indicative of the sensed temperature; and a controller coupled to control the at least one power semiconductor switch and to receive the temperature signal from the temperature sensor. The controller is configured to: determine whether the temperature signal is indicative of a temperature of the one or more power semiconductor switch exceeding a threshold; and when the temperature signal is indicative of the temperature of the one or more power semiconductor switch exceeding the threshold, turn off or reduce a power output of the at least one power semiconductor switch.

Turning off or reducing a power output in this manner may reduce the chance of damage, and/or improve the longevity, of the at least one power semiconductor switch.

The haircare appliance may comprise an airflow path, the airflow path having disposed within it: an airflow generator for moving air downstream through the airflow path; and the heater.

At least a portion of the at least one power semiconductor switch may be in contact with air flowing through the air flow path, thereby to cool the at least one power semiconductor switch when the haircare appliance is in use.

The controller may be configured to, when the temperature signal is indicative of the temperature of the at least one power semiconductor switch exceeding the threshold, reduce a power output of the at least one power semiconductor switch until the temperature signal is indicative of the temperature of the at least one power semiconductor switch beginning to fall. This may reduce the chance of damage, and/or improve longevity, of the at least one power semiconductor switch, while enabling the haircare appliance to continue operating. The controller may be configured to keep the power output of the at least one power semiconductor switch reduced until the temperature signal is indicative of the temperature of the at least one power semiconductor falling below the threshold.

The controller may be configured to, after the temperature signal is indicative of the temperature of the at least one power semiconductor falling below the threshold, control the power output of the at least one power semiconductor switch to maintain the temperature of the at least one power semiconductor below the threshold. This may reduce the chance of damage, and/or improve longevity, of the at least one power semiconductor switch, while enabling the haircare appliance to continue operating.

The controller may be configured to: determine whether the temperature signal is indicative of a temperature of the one or more power semiconductor switches exceeding a further threshold; and when the temperature signal is indicative of the temperature of the one or more power semiconductor switches exceeding the further threshold, turn off the at least one power semiconductor switch.

The at least one power semiconductor switch comprises at least one TRIAC.

The temperature sensor may be mounted in contact with at least one of the at least one power semiconductor switch.

The temperature sensor may be mounted within a cavity of the haircare appliance, at least a portion of the at least one power semiconductor switch extending into, or being in contact with a wall of, the cavity, such that the temperature sensor is arranged to sense the temperature of the at least one power semiconductor switch indirectly by sensing the temperature of the air within, or the wall of, the cavity.

According to a second aspect, there is provided a method performed by a haircare appliance comprising: a heater; at least one power semiconductor switch coupled to drive, in use, the heater; and a temperature sensor disposed for sensing a temperature of the one or more power semiconductor switches and outputting a temperature signal indicative of the sensed temperature. The method comprises: receiving the temperature signal from the temperature sensor; determining whether the temperature signal is indicative of a temperature of the one or more power semiconductor switches exceeding a threshold; and when the temperature signal is indicative of the temperature of the one or more power semiconductor switches exceeding the threshold, turning off or reducing a power output of the at least one power semiconductor switch.

The method may comprise: when the temperature signal is indicative of the temperature of the at least one power semiconductor switch exceeding the threshold, reducing a power output of the at least one power semiconductor switch until the temperature signal is indicative of the temperature of the at least one power semiconductor switch beginning to fall. The method may also comprise keeping the power output of the at least one power semiconductor switch reduced until the temperature signal is indicative of the temperature of the at least one power semiconductor falling below the threshold. The method may also comprise, after the temperature signal is indicative of the temperature of the at least one power semiconductor falling below the threshold, controlling the power output of the at least one power semiconductor switch to maintain the temperature of the at least one power semiconductor below the threshold.

The method may comprise: determining whether the temperature signal is indicative of a temperature of the one or more power semiconductor switches exceeding a further threshold; and when the temperature signal is indicative of the temperature of the one or more power semiconductor switches exceeding the further threshold, turning off the at least one power semiconductor switch.

The temperature sensor may be mounted within a cavity of the haircare appliance, at least a portion of the at least one power semiconductor switch extending into, or being in contact with a wall of, the cavity, and the method may comprise: sensing, with the temperature sensor, the temperature of the at least one power semiconductor switch indirectly by sensing the temperature of the air within, or the wall of, the cavity.

According to a third aspect, there is provided a haircare appliance comprising: a processor having a first input; a temperature processing circuit separate to the processor, the temperature processing circuit having a second input; and a temperature sensor for sensing a temperature within the haircare appliance and outputting a temperature signal indicative of the sensed temperature, the temperature signal being supplied, in use, to the first and second inputs in parallel. The haircare appliance comprises a buffer disposed in series between: the first input; and the second input and the temperature sensor; the buffer preventing or mitigating an effect on the second output of a signal generated on the first input.

The buffer prevents or mitigates an effect on the second input of a signal generated on the first input.

The processor may comprise an analog-to-digital convertor, the first input being an input of the analog-to-digital converter. The processor may also comprise one or more processing units.

The analog-to-digital converter and the one or more processing units may be in the same physical package, or the analog-to-digital converter may be in a different package to the one of more processing units.

The processor may be disposed in a first housing and the temperature sensor may be disposed in a second housing, the first and second housings being connected by a cable, the cable including at least one communication link for communicating the temperature signal from the temperature sensor to the first input. The temperature processing circuit may be disposed in the first housing.

The processor and the temperature sensor may be disposed in a housing. The temperature processing circuit may also be disposed in the housing.

The haircare appliance may include: an airflow path; an airflow generator for moving air downstream through the airflow path; and a heater for heating the air. The temperature sensor may be an air temperature sensor configured to sense a temperature of heated air within the airflow path, or a heater temperature sensor configured to sense temperature of the heater.

The temperature sensor may be a resistance temperature detector or a thermistor.

At least one processing unit associated with the processor may be configurable such that the first input is usable as an output, whether or not such configurability is possible by a user of the haircare appliance.

The haircare appliance may take the form of a hair dryer.

According to a fourth aspect, there is provided a method of operating a haircare appliance, comprising: generating a temperature signal indicative of a temperature associated with a portion or region of the haircare appliance; and supplying the temperature signal, in parallel, to: a first input of a processor via a buffer; and a second input of a temperature processing circuit separate to the processor; the buffer preventing or mitigating an effect on the second output of a signal generated on the first input.

According to a fifth aspect, there is provided a heating circuit comprising: a heater comprising a first terminal and a second terminal, the first terminal being coupled, in use, with a live circuit or a neutral circuit of an AC power supply; a heater drive circuit coupled in series with the heater, the heater drive circuit comprising a first heater drive connection for coupling to the second terminal, a second heater drive connection being coupled, in use, with the other of the live circuit and the neutral circuit not coupled with the first terminal of the heater, and a heater drive control input for receiving a first control signal; a control circuit coupled to control switching of the heater drive circuit, the control circuit comprising a first control circuit connection for coupling to the neutral or live circuit of the AC power supply, a second control circuit connection for coupling to the heater drive control input, and a control circuit control input for receiving a second control signal, the control circuit being responsive to the second control signal to generate the first control signal; a controller for outputting the second control signal at a controller output; and a capacitive circuit in series between the controller output and the control circuit control input, such that, in the event of an error or failure causing the controller output to output the second control signal such that the heater would erroneously be driven by the heater drive circuit, the capacitive circuit prevents the control circuit from actuating the heater drive circuit.

The heater drive circuit may comprise a power semiconductor switch including the first heater drive connection and the second heater drive connection.

The power semiconductor switch may comprise a TRIAC, the heater drive control input comprising a control terminal of the TRIAC.

The control circuit may comprise a control switch comprising the control circuit control input, a first terminal coupled with a first power supply voltage, and a second terminal.

The control circuit may comprise an opto-TRIAC comprising the first control circuit connection, the second control circuit connection, a third terminal coupled with a second power supply voltage different to the first power supply voltage, and a fourth terminal coupled with the second terminal.

The second control signal may comprise a series of pulses that cause the control switch generate a voltage across the capacitive circuit, such that: while the voltage across the capacitive circuit remains above a threshold, the control circuit generates the first control signal; and when the voltage across the capacitive circuit falls below the threshold, the control circuit does not generate the first control signal.

The heating circuit may be configured such that, if the second control signal remains at a constant voltage, the capacitive circuit discharges until the voltage across it falls below the threshold.

The capacitive circuit may comprise a series-coupled capacitor.

According to a sixth aspect, there is provided a haircare appliance comprising the heating circuit of the preceding aspect.

According to a seventh aspect, there is provided a method of controlling power supplied to a heater disposed within an airflow path of a haircare appliance, the heater being coupled to be driven by an AC power supply modulated by drive circuitry, the method comprising repeatedly:
determining a resistance of the heater;
based on the determined resistance, controlling the drive circuitry modulation such that:
an average drive voltage supplied to the heater increases as the temperature of the heater increases; and
the power supplied to the heater does not exceed a maximum power while the temperature of the heater increases.

Controlling the drive circuitry modulation in this manner reduces inrush current while prevent a maximum power being exceeded.

The method may comprise controlling the drive circuitry modulation so as to maximise the power supplied to the heater without exceeding the maximum power. This maximises the rate at which the appliance reaches full operating temperature.

Determining a resistance of the heater may comprise receiving a signal from a thermal sensor disposed within the haircare appliance to sense a temperature of the heater, the signal being indicative of the temperature of the heater. The thermal sensor comprises a resistance temperature detector, and the signal may comprise a voltage correlated with a resistance of the resistance temperature detector.

Controlling the drive circuitry modulation may comprise adjusting a duty cycle of the AC power supply. For example, controlling the drive circuitry modulation may comprise phase angle controlling and/or burst fire controlling the AC power supply.

The maximum power may comprise an available power, the available power comprising a difference between a power rating of the haircare appliance and a power consumption of other components of the haircare appliance. The power consumption of the other components may, for example, be based on a nominal power consumption of at least some of the components.

The maximum power may comprise a current-limited power, and the method may comprise determining the current-limited power based on the supply voltage, and a predetermined maximum current defined for the appliance and/or one or more components of the appliance. This provides additional protection.

The method may comprise repeatedly measuring the supply voltage for use in determining the current-limited power. This approach provides better performance when the supply voltage varies from the nominal supply voltage.

The method may comprise repeatedly setting the maximum power by:
determining an available power, the available power comprising a difference between:
   a power rating of the haircare appliance; and
   a power consumption of other components of the haircare appliance;
determining a current-limited power based on the supply voltage, and a predetermined maximum current defined for the appliance and/or one or more components of the appliance; and
selecting the lesser of the available power and the current limited power as the maximum power.

According to an eight aspect, there is provided a haircare appliance comprising:
a heater disposed within an airflow path of a haircare appliance;
a sensor mounted with or adjacent to the heater, and configured to generate a signal indicative of a resistance of the heater;
drive circuitry coupled to modulate an AC power supply for driving the heater; and
a controller configured to:
   receive the signal;
   determine, based on the signal, a control signal for controlling the drive circuitry; and
   output the control signal to control the drive circuitry modulation; such that:
   an average drive voltage supplied to the heater increases as the temperature of the heater increases; and
   the power supplied to the heater does not exceed a maximum power while the temperature of the heater increases.

The controller may be configured to determine the control signal such that the drive circuitry modulation maximises the power supplied to the heater without exceeding the maximum power.

The thermal sensor may comprise a resistance temperature detector, and the signal may comprise a voltage correlated with a resistance of the resistance temperature detector.

The control signal may adjust a duty cycle of the AC power supply. For example, the control signal may cause the drive circuitry to modulate the AC power supply by phase angle control and/or burst fire control.

The maximum power may comprise an available power, the available power comprising a difference between a power rating of the haircare appliance and a power consumption of other components of the haircare appliance. The power consumption of the other components may be based on a nominal power consumption of at least some of the components.

The maximum power may comprise a current-limited power, and the controller may be configured to determine the current-limited power based on the supply voltage and a predetermined maximum current defined for the appliance and/or one or more components of the appliance.

The haircare appliance may comprise voltage determining circuitry for measuring the supply voltage for use in determining the current-limited power.

The haircare appliance may be a hair-dryer, and the heater may be disposed within an airflow path of the hair-dryer.

According to a ninth aspect, there is provided a method of controlling a hair care appliance, the hair care appliance including a driving circuit and a heater configured to be driven by the driving circuit, the method comprising:
sensing a temperature associated with one or more components of the hair care appliance, and/or an airflow through an airflow path of the hair care appliance;
determining, in software and based on the sensed temperature, whether a first temperature threshold has been exceeded;
determining, in a hardware circuit and based on the sensed temperature, whether a second temperature threshold has been exceeded; and
when the first temperature threshold and/or the second temperature threshold has been exceeded, controlling the driving circuit to reduce or halt drive to the heater.

The method may comprise delaying an output of the hardware circuit, so as to increase a likelihood of the first temperature threshold being exceeded before the second temperature threshold.

Delaying the output may comprise filtering and/or delaying the sensed temperature at input to the hardware circuit, and/or delaying an output of the hardware circuit.

Delaying may comprise filtering comprises low-pass filtering and/or scaling.

The first temperature threshold may be lower than the second threshold, thereby to increase a likelihood that the first threshold will be exceeded before the second threshold as the sensed temperature rises from below the first threshold.

The driving circuit may comprise at least one power semiconductor switch, and controlling the driving circuit may comprise changing a drive input to the power semiconductor switch.

The at least one semiconductor switch may comprise a low-power semiconductor switch comprising the drive input, and the high-power semiconductor switch may be driven by the low-power semiconductor switch.

The low-power semiconductor switch may be an opto-TRIAC and/or the high-power semiconductor switch may be a TRIAC.

Sensing the temperature may comprise sensing a plurality of the temperatures of more than one of the components and/or the airflow, the method comprising:
determining, in software and based on the sensed temperatures, whether any of a first plurality of temperature thresholds including the first temperature threshold has been exceeded; and
when any of the first plurality of temperature thresholds has been exceeded, controlling the driving circuit to reduce or halt drive to the heater.

The method may comprise:
determining, in the hardware circuit and based on the sensed temperatures, whether any of a second plurality of temperature thresholds including the second threshold has been exceeded; and
when any of the second plurality of temperature thresholds has been exceeded, controlling the driving circuit to reduce or halt drive to the heater.

The values of the first and second plurality of thresholds may be such that a temperature of any given component or airflow will be more likely to exceed one or more of the thresholds as a result of the software determination than as a result of the hardware determination.

If at least one of the thresholds is exceeded as a result of the software determination, the method may comprise increasing the drive to the heater automatically or in response to user input.

If at least one of the thresholds is exceeded as a result of the hardware circuit determination, then reducing or halting drive to the heater is not resettable automatically or in response to user input.

Sensing the temperature may comprise outputting, from one or more temperature sensors, one or more temperature signals indicative of the temperature associated with one or more components of the hair care appliance, and/or an airflow.

According to a tenth aspect, there is provided a hair care appliance comprising:
a driving circuit;
a heater configured to be driven by the driving circuit;
one or more temperature sensors configured to output one or more temperature signals indicative of a temperature associated with one or more components of the hair care appliance, and/or an airflow through an airflow path of the hair care appliance;
a processor configured to receive the one or more temperature signals; and
a hardware circuit configured to receive the one or more temperature signals;
the hair care appliance being configured to:
   determine, using software executed in the processor and based on the one or more temperature signals, whether a first temperature threshold has been exceeded;
   determine, in the hardware circuit and based on the one or more temperature signals, whether a second temperature threshold has been exceeded; and
   when the first temperature threshold and/or the second temperature threshold has been exceeded, control the driving circuit to reduce or halt drive to the heater.

The hair care appliance may be configured to implement the method of the ninth aspect.

Optional features of aspects of the present invention may be equally applied to other aspects of the present invention, where appropriate.

### BRIEF DESCRIPTION OF DRAWINGS

FIG. 1 is a perspective view of an embodiment of a haircare appliance;

FIG. 2 is a schematic view illustrating internal components of the haircare appliance of FIG. 1;

FIG. 3 is a schematic longitudinal section of a heater housing of the haircare appliance of FIGS. 1 and 2;

FIG. 4 shows a method of generating a filtered target temperature, for use with the haircare appliance of FIGS. 1-3;

FIG. 5 is a graph showing a relationship between resistance and temperature of a heater trace;

FIG. 6 shows a method of controlling power supplied to a heater, performed by the haircare appliance of FIGS. 1-3;

FIG. 7 shows a method of controlling power supplied to a heater, performed by the haircare appliance of FIGS. 1-3;

FIG. 8 shows a circuit for controlling a power TRIAC with a microcontroller unit (MCU), forming part of the haircare appliance of FIGS. 1-3;

FIG. 9 shows a circuit for outputting a signal indicative of a temperature of a TRIAC, forming part of the haircare appliance of FIGS. 1-3;

FIG. 10 shows a method of turning off or reducing power to a TRIAC, performed by the haircare appliance of FIGS. 1-3;

FIG. 11 shows an alternative method of controlling power supplied to a heater, performed by the haircare appliance of FIGS. 1-3;

FIG. 12 shows an example of a TRIAC drive pattern employing burst fire mode; and

FIG. 13 shows an example of a TRIAC drive pattern employing a combination of burst fire and phase angle control.

### DETAILED DESCRIPTION

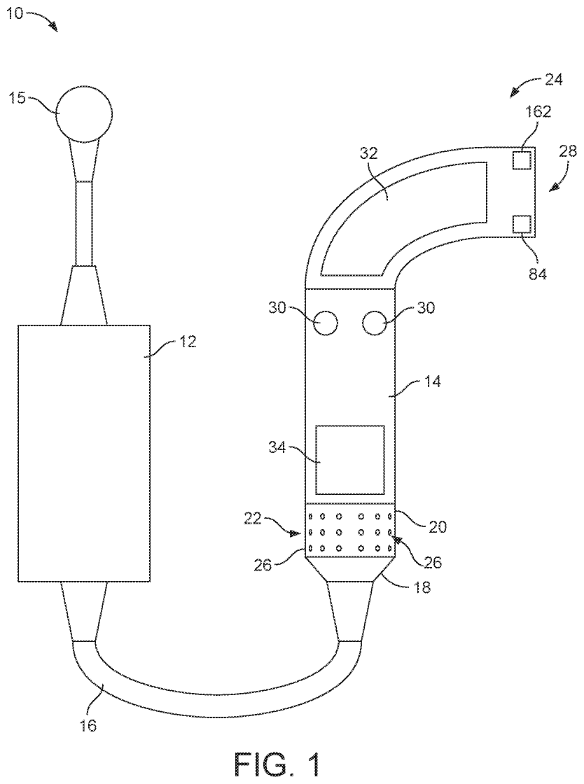

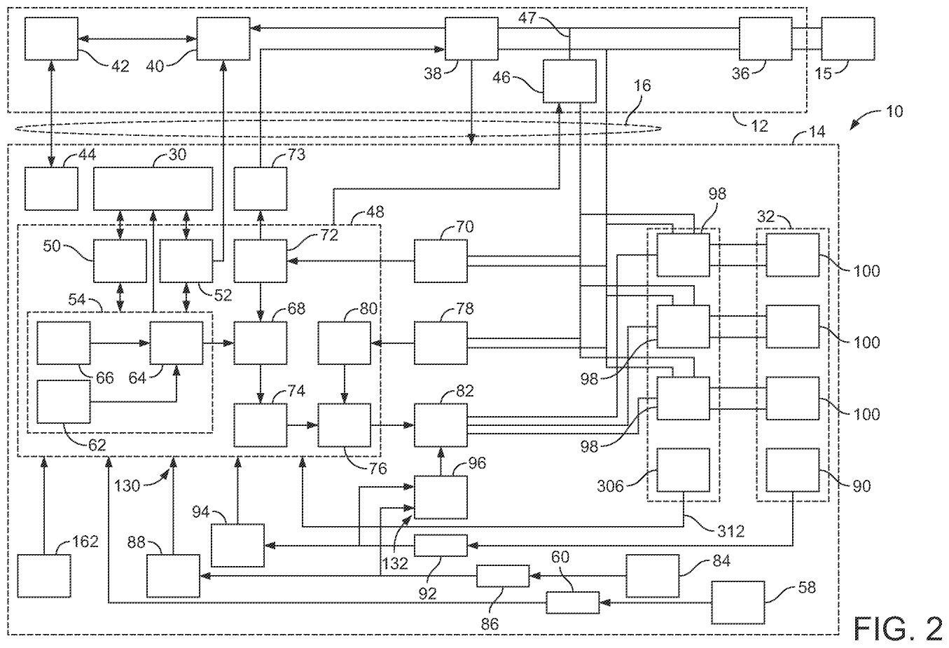

A haircare appliance, generally designated 10, is shown schematically in FIGS. 1 and 2. The haircare appliance 10 in the embodiment of FIGS. 1 and 2 is a hairdryer, although it will be appreciated that some of the teachings discussed herein may be applied to other types of haircare appliance, for example hair straighteners or hair curlers or the like.

The haircare appliance 10 comprises a circuitry housing 12, a heater housing 14, and an electrical cable 16 extending from the circuitry housing 12 to the heater housing 14. The circuitry housing 12 defines an enclosure that houses a number of electronic components as will be described hereinafter, and the electronic components within the circuitry housing 12 are coupled to corresponding electronic components within the heater housing 14 by wires held within the electrical cable 16. Whilst referred to as wires, it will be appreciated that each wire may comprise more than one electrically conducting filament, for example as is the case with a braided wire, with the overall structure of multiple filaments being considered a wire. A power connector 15 in the form of a plug is coupled to the opposite side of the circuitry housing 12 to the electrical cable 16. The power connector 15 is configured to interact with an AC mains power supply, for example via a mains socket (not shown), to provide electrical current to the haircare appliance 10 in use.

The heater housing 14 defines a hollow, generally elongate, handle that is intended to be grasped by a user in use. As seen in FIG. 1, the heater housing 14 comprises a conical end portion 18 and a wall 20 extending upwardly from the conical end portion 18, such that a first end 22 of the heater housing 14 is generally cylindrical in form. The heater housing 14 has a second end 24 distal from the first end 22, and the heater housing 14 is curved such that the second end 24 is angled relative to the first end 22. An air inlet 26 is located at the first end 22 of the heater housing 14 on the wall 20, and takes the form of a plurality of apertures, for example in a mesh-like structure. An air outlet 28 is located at the second end 24, and comprises an aperture through which air may flow in use.

A user interface 30 is formed on the wall 20, and may take the form of a plurality of buttons, a touchscreen, or a combination thereof. User interface 30 allows a user to input various desired settings that are used by the other components of the haircare appliance 10 to control heat and fan settings, and may also provide visual and/or audible feedback, as described in more detail below.

A heater 32 and an airflow generator 34 are disposed within the heater housing 14.

Turning to FIG. 2, the internal components and functional features of the haircare appliance 10 will be described in more detail. The skilled person will appreciate that the components and features are set out in schematic form, and that the relative positions and sizes of those components and features of the actual appliance may vary from what is illustrated in FIG. 2.

Power connector 15 supplies, in use, AC mains power into circuitry housing 12. The AC mains power is supplied to a mains filter 36, which filters the AC mains power. Operation of the mains filter 36 is described in more detail below.

The AC output of the mains filter 36 is supplied to the input of an AC-to-DC converter 38. The AC-to-DC converter 38 converts the incoming AC voltage to DC, outputting various DC voltages as required by different components of the haircare appliance 10, as described in more detail below.

One output of the converter 38 is a DC power supply to a fan motor controller 40. Fan motor controller 40 receives control signals as described in more detail below, and outputs a fan motor drive signal to an electromagnetic compatibility (EMC) filter 42. The EMC filter 42 outputs the filtered fan motor drive signal to a fan motor 44. The EMC filter filters out harmonics generated by the fan motor 44, in use. The fan motor 44 forms part of the airflow generator 34, as described in more detail below.

Fan motor 44 may take the form of, for example, a V9 Dyson Digital Motor by Dyson Technology Limited. The V9 Dyson Digital Motor is a single-phase motor. Use of a single-phase motor may reduce the number of wires required to extend from circuitry housing 12 to heater housing 14 compared to, for example a similar arrangement where a three-phase motor is utilised by the airflow generator 34 within heater housing 14. Alternatively, a three-phase motor may be used to obtain a smaller and/or lighter heater housing 14.

The output of mains filter 36 also supplies the filtered AC mains power to heater housing 14 via electrical cable 16. Circuitry housing 12 also includes a relay 46, for selectively switching live circuit 48 of the AC mains power. Control of relay 46 is described in more detail below.

Several of the features and components of the haircare appliance 10 are implemented in a microcontroller unit (MCU) 48, as described in more detail below. The MCU 48 includes a processor, memory, and other components necessary to implement the features and components described herein. Although the example describes the use of a haircare appliance 10 having a single MCU 48 disposed within heater housing 14, it will be appreciated that the MCU 48 may be located within circuitry housing 12. Alternatively, implementation of the features and components of the haircare appliance 10 may be distributed across two or more processors, located within circuitry housing 12, heater housing 14, or both. Additional supporting circuitry, such as communications and power, are omitted for clarity. An example of a suitable MCU is the ARM Cortex-M0+.

User interface 30 allows a user to set a target temperature 50 and a fan speed 52. Target temperature 50 and fan speed 52 may each be selectable from a relatively small number of options (e.g., high, medium and low settings for each of target temperature 50 and fan speed 52). Alternatively, either or both of the target temperature 50 and fan speed 52 may be selected in a more granular way. For example, target temperature may be chosen as a specific temperature in degrees C. or F, to a resolution of, say, 5, 10 or 20°. Similarly, fan speed 52 may be chosen as a specific airflow, such as in litres per second.

Target temperature 50 and fan speed 52 are stored within MCU 48. They may be stored persistently or reset to default values at each start-up of the haircare appliance 10.

Fan speed 52 is provided as an input to fan motor controller 40 and to a control block 54 within MCU 48, and target temperature 50 is supplied to control block 54, as described in more detail below.

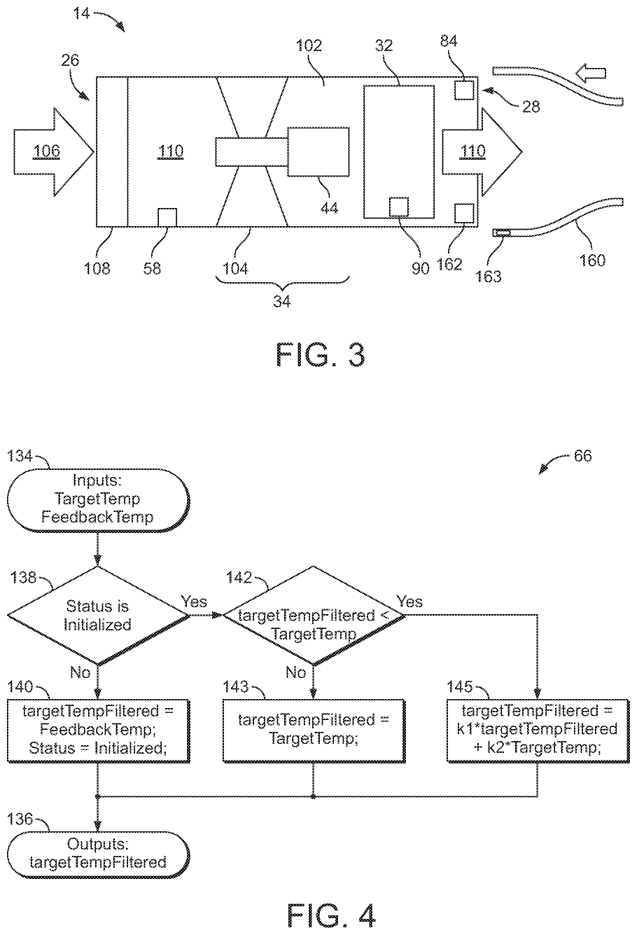

As described in more detail below in relation to FIG. 3, heater housing 14 includes an air pressure sensor in the form of a barometer 58. Barometer 58 provides a raw pressure signal to pressure processing circuitry 60, which includes scaling and filtering circuitry that processes the raw pressure signal before outputting it as a pressure value. Such circuitry is well known to the skilled person and so will not be described in more detail. The pressure value is provided as an input to MCU 48, where it is used as described below. The pressure value may be, for example, the instantaneous pressure value based on the raw pressure signal from barometer 58. Alternatively, the pressure value may be low-pass filtered to reduce the impact of, for example, noise or spurious short-term pressure changes.

As described in more detail below in relation to FIG. 3, heater housing 14 includes an air exit temperature (AET) sensor 84. AET sensor 84 provides a raw temperature signal to AET processing circuitry 86, which includes scaling and filtering circuitry that processes the raw temperature signal before outputting it as a temperature value. Such circuitry is well known to the skilled person and so will not be described in more detail. The temperature value may be, for example, the instantaneous temperature value based on the raw signal from AET sensor 84. Alternatively, the temperature value may be low-pass filtered to reduce the impact of, for example, noise or spurious short-term temperature changes.

The temperature value is provided as an input to an AET buffer 88, as described in more detail below. AET buffer 88 provides a buffered temperature value as an input to MCU 48, where it is used as described in more detail below.

Heater housing 14 includes a heater temperature sensor 90, positioned to sense a temperature of heater 32. Heater temperature sensor 90 provides a raw temperature signal to heater temperature processing circuitry 92, which includes scaling and filtering circuitry that processes the raw temperature signal before outputting it as a temperature value. Such circuitry is well known to the skilled person and so will not be described in more detail. The temperature value is provided as an input to a heater temperature buffer 94, as described in more detail below. Heater temperature buffer 94 provides a buffered temperature value as an input to MCU 48, where it is used as described in more detail below.

Pressure processing block 62 within control block 54 processes the pressure and temperatures value as described in more detail below, and outputs control information to a power controller 64 within control block 54. Target smoothing block 66 processes the target temperature 50 as described in more detail below, and outputs power target information to power controller 64. Based on the received control information and power target information, power controller 64 outputs a power control signal to a current controller 68.

The AC power supply provided from circuitry housing 12 to heater housing 14 via electrical cable 16 is supplied as an input to a voltage sensing circuit 70. Voltage sensing circuit 70 may comprise, for example, an analogue to digital converter for sampling a voltage of the AC power supply and converting it to a numerical value that can be used by MCU 48. The output voltage sensing circuit 70 is provided to an RMS voltage calculator 72, which determines an RMS voltage of the AC power supply, as described in more detail below.

The calculated RMS voltage is provided as an input to current controller 68. The calculated RMS voltage is also provided as an input to a voltage check block 73. Voltage check block 73 determines whether the calculated RMS voltage is above a threshold (or, alternatively, below a threshold, or between two thresholds), and outputs a gate control signal to the converter 38, as described in more detail below.

Current controller 68 uses the RMS voltage and power control signal to determine a desired power output, which may be in the form of an instantaneous or average desired current, power, or combination thereof. The desired output is provided as an input to a TRIAC pattern calculator 74. TRIAC pattern calculator 74 uses the desired output to generate a suitable TRIAC drive pattern. For example, the TRIAC pattern calculator 74 may use a burst-fire control scheme, a phase angle control scheme, or a combination thereof, to generate a TRIAC drive pattern to control current flow to heater elements, as described in more detail below. The TRIAC drive pattern is provided as an input to TRIAC drive signal generator 76.

The AC power supply provided from circuitry housing 12 to heater housing 14 via electrical cable 16 is also supplied as an input to a zero-crossing detection circuit 78. The zero-crossing detection circuit 78 determines zero-crossing points of the AC power supply, as described in more detail below, and provides them as an input to a delay compensation block 80 within MCU 48. The delay compensation block 80 determines a suitable delay compensation value and provides this as an input to TRIAC drive signal generator 76.

TRIAC drive signal generator 76 converts the TRIAC drive pattern into suitable TRIAC drive signals and applies appropriate delay compensation, as described in more detail below. The TRIAC drive signals are output from MCU 48 and provided as an input to TRIAC drive circuit 82.

The AET temperature and heater temperature are also provided as inputs to overheat protection circuitry 96. Overheat protection circuitry 96 operates to determine when the AET temperature and/or heater temperature exceed various thresholds, and provides overheat control signals to TRIAC drive circuit 82 so that appropriate action can be taken, as described in more detail below.

TRIAC drive circuit 82 outputs TRIAC drive signals to TRIACs 98, and the TRIACs 98 are also coupled to receive the AC power supply, as described in more detail below. Although three TRIACs are illustrated, the skilled person will appreciate that any suitable number of TRIACs may be driven by the TRIAC drive signals.

Each TRIAC 98 drives a heater element 100 within heater 32. Each heater element 100 may take the form of, for example, a resistive trace on a heat-resistant substrate, such as a resistive wire wound around an insulating scaffold. Alternative types of heater can use a heater track printed onto a polyamide sheet such as Kapton or a ceramic heater coupon having an embedded heater track formed from a trace made from an electrically conductive material such as but not limited to tungsten. In order to dissipate heat from the ceramic heater coupon cooling fins may be provided. Each heater element 100 is exposed to air flowing through an air flow path of the haircare appliance 10, as described in more detail below.

FIG. 3 shows a simplified schematic and partially sectioned view of the heater housing 14 and some of the components it contains. Many of the features and components described in relation to FIGS. 1 and 2, including the bend in heater housing 14, have been omitted for clarity.

FIG. 3 shows schematically an air flow path 102 defined within heater housing 14. Airflow generator 34 comprises the fan motor 44 and an axial impeller 104. Fan motor 44 drives impeller 104 to generate airflow. Air is initially sucked through air inlet 26, as shown by an air-in arrow 106. The air passes through an inlet filter 108, which filters particles such as dust and hair from the air before it passes into the airflow path 102. In use, resistance offered by inlet filter 108 causes a reduced pressure region 110 between inlet filter 108 and impeller 104. Pressure sensor 58 is disposed within this region, to allow sensing of pressure changes as described in more detail below.

Air moves through impeller 104 and past motor 44, cooling motor 44 as it passes. The air is then heated as it passes through heater 32. The temperature of heater 32 is monitored by heater temperature sensor 90, as described in more detail below. Air then passes AET sensor 84, before exiting outlet 28 as shown by an air-out arrow 110.

Haircare appliance 10 may be used with one or more optional detachable accessories, such as a flow-accelerating accessory 160 as shown in FIG. 3. Accessory 160 may be releasably attached at or adjacent air outlet 28 to control the shape, direction and speed, for example, of the airflow. Haircare appliance 10 includes a sensor or scanner, such as ID sensor 162, that allows an attached airflow accessory to be identified.

An attached airflow accessory 160 may be identified in any of a number of ways. For example, the accessory 160 may include an identifier that can be sensed or scanned by corresponding ID sensor 162.

The identifier may take the form of a circuit that can communicate the identifier. For example, the identity can be encoded by an identifier in the form of an RFID or near field communication (NFC) device 163 disposed in or on a portion of the accessory. In that case, ID sensor 162 takes the form of a corresponding RFID/NFC scanner provided on or in the haircare appliance 10.

The identifier may, alternatively or in addition, take the form of a scannable image, that may be printed, embossed, engraved, 3-D-printed, or otherwise disposed in a scannable form onto or into a surface of the airflow accessory 160. The scannable image may take the form of, for example, a QR-code, a barcode, alphanumeric text, or any other suitable form of machine-readable image. The ID sensor 162 takes the form of a corresponding sensor or scanner, located in or on the heater housing 14 (or a main housing, in the event the haircare accessory is not formed of separate circuitry housing 12 and heater housing 14). The ID sensor 162 may operate optically (whether or not in the visible spectrum), ultrasonically, or electromagnetically, or based on any other suitable technology, or combination of such technologies.

The identifier may alternatively, or in addition, take the form of a physical shape or shapes that encode an identifier. For example, one or more raised ribs, lands, fingers, or recessed portions on the accessory can interact with a corresponding tongue, pin, tang, lever, or other physical element that is connected to, for example, a switch on heater housing 14, such as a physical, optical or electromagnetic switch.

The identifier may alternatively, or in addition, take the form of a magnetic or electromagnetic portion that can be sensed by a corresponding magnetic- or electromagnetic-sensitive switch or sensor.

Whatever approach is taken to identifying an attached airflow accessory, in general, installation of the accessory 160 onto the heater housing 14 results in the ID sensor 162 or scanner being positioned adjacent the identifier 163 (or the structure or mechanism by which the identifier is encoded). The scanner or sensor can then sense or scan the identifier value, allowing the haircare appliance 10 to identify the attached accessory 160.

The identifier can be, for example, an index, the haircare appliance 10 having a memory that stores a table mapping each index to information that allows airflow calculations to take into account the attached accessory. For example, the information may comprise a correction factor related to the identified accessory, allowing the airflow calculations to be suitably corrected for the impact of the attached accessory. Alternatively, the identifier may directly encode the information. For example, the identifier may store a number representative of a correction factor related to the accessory.

The identifier can encode multiple bits, representing several potential accessories and/or indices, allowing a correction factor to be used that best corresponds to a particular accessory that is attached. Alternatively, the identifier may effectively encode a single bit of information, allowing the haircare appliance 10 to identify the simple presence or absence of an accessory. This enables a single correction factor to be applied for all accessories, if attached. Although this may be limiting where multiple possible accessories are possible, simple presence/absence detection has the benefit of simplicity and potentially higher reliability.

As described above, haircare appliance 10 includes AET buffer 88 and heater temperature buffer 94. Operation of AET buffer 88 will now be described in detail.

As shown in FIG. 2, an output of AET processing circuitry 86 is provided to AET buffer 88, an output of which is provided to a first input 130 of MCU 48. The output of AET processing circuitry 86 is also provided to a second input 132, in the form of an input to a temperature processing circuit in the form of overheat protection circuitry 96. This results in the output of AET processing circuitry 86 being provided to first input 130 and second inputs 132 in parallel. Also, AET buffer 88 is disposed in series between: the first input 130; and the second input 132 and the AET sensor (by way of AET processing circuitry 86).

The position of AET buffer 88 prevents or mitigates an effect on the second input 132 of a signal generated on the first input 130. Such a situation may arise due to, for example a hardware or software malfunction of the MCU 48.

Another potential source of such a situation is where first input 132 of MCU 48 is configurable, whether or not such configurability is possible by a user of haircare appliance 10. In the event first input 132 is incorrectly configured as an output, AET buffer 88 will prevent any spurious signal generated on that output (i.e., reconfigured input 130) from affecting overheat protection circuitry 96. This results in safer operation of haircare appliance 10.

First input 130 may be connected to an input of an analog-to-digital converter (not shown). Such an analog-to-digital converter may be within the same package as MCU 48, or may be provided as a separate component providing a numerical value is an output, which is in turn input to MCU 48.

Although haircare appliance 10 shown in FIGS. 1-3 shows AET temperature sensor 84 and AET buffer 88 as being within the heater housing 14 along with MCU 48, alternatively, any of the components may be disposed in a different housing to that shown. In yet other alternatives, the haircare apparatus 10 comprises only a single housing for all components.

It will be appreciated that the description and advantages of AET buffer 88 apply equally to heater temperature buffer 94, and so the latter will not be described separately in detail.

AET sensor 84 and heater temperature sensor 90 may take any suitable form. For example, the heater temperature sensor 90 may be a resistance temperature detector (RTD) and the AET sensor 84 may be a thermistor. Alternatively, any suitable temperature sensor may be used for either role.

The use of a buffer, such as AET buffer 88 and heater temperature buffer 94, may also be implemented as a method of operating a haircare appliance, such as haircare appliance 10. The method comprises generating a temperature signal indicative of a temperature associated with a portion or region of the haircare appliance (such as the air exit temperature and/or heater temperature). The temperature signal is supplied, in parallel to a first input of a processor (such as MCU 48) and a second input of a temperature processing circuit (such as overheat protection circuitry 96). The buffer is used to prevent or mitigate an effect on the second output of a signal generated on the first input.

Target smoothing function 66 accepts target temperature 50 as an input. Target smoothing function 66 is an optional feature that may reduce temperature response overshoot, especially upon start-up of haircare appliance 10.

As shown in FIG. 4, target smoothing function 66 has as inputs 134 variables TargetTemp and FeedbackTemp. TargetTemp is the target temperature 50 selected via the user interface. FeedbackTemp is a value used to initialise the function implemented by target smoothing function 66, to avoid unusual output values while the target smoothing function builds up a sufficient history of values.

While the target smoothing function 66 is running, its output 136 is the value of a variable targetTempFiltered. Variable targetTempFiltered is the output of target smoothing function 66 that is provided as an input to power controller 64.

An assessment 138 is made as to whether the status of target smoothing function 66 is “initialised”. If not, in step 140, a value of output targetTempFiltered is set to FeedbackTemp, and the status is changed to “initialised”.

Once the status is initialised in step 140, the output of assessment 138 becomes “yes”, and the method moves on to an assessment 142 of whether targetTempFiltered is less than TargetTemp. If the answer of assessment 142 is “no”, the method moves to step 143, in which the value of output targetTempFiltered is set to TargetTemp. Alternatively, if the answer of assessment 142 is “yes”, the value of output targetTempFiltered is set 145 to: k1*targetTempFiltered+k2*TargetTemp

Values of k1 and k2 are determined empirically, such as by modelling and/or testing, for each type of haircare appliance. The value of k1 may be larger than k2. For example, the value of k1 may be at least 10 times that of k2. The sum of k1 and k2 may be 1, but the skilled person will appreciate that a different sum may be used depending on the desired behaviour of target smoothing function 66. In one example, k1=0.98 and k2=0.2. In another example, k1=0.9804 and k2=0.0196.

The net effect of the target smoothing function 66 is to provide a smoothed target temperature to a subsequent power controller, such as power controller 64. Such a power controller may implement power control using some combination of proportional, integral and differential control loop. By providing a smoothed target temperature as an input to such a power controller, the slope of the change in target temperature over time may be limited, which may help reduce temperature overshoot. The skilled person will appreciate that a power control loop implemented by such a power controller may need modification to take into account the effect of target smoothing function 66, and will understand how to implement any such required modifications.

Returning to power controller 64 within control block 54, pressure processing block 62 processes the pressure and temperature values as described above, and outputs control information to a power controller 64 within control block 54. Target smoothing block 66 processes the target temperature 50 as described above, and outputs power target information to power controller 64.

Based on the received control information from pressure processing block 62 and power target information from target smoothing block 66, power controller 64 outputs a power control signal to current controller 68. The power target information represents a target temperature for air exiting airflow path 102.

Power controller 64 may take the form of a closed loop controller. For example, power controller 64 as illustrated is a proportional-integral (PI) controller, outputting a power control signal to current controller 68. The power control signal may be an absolute target power, or a power difference signal, depending upon operation of current controller 68.

PI-controllers are generally well understood, and so the operation of power controller 64 will not be described in detail. However, the power controller 64 optionally uses different proportional and integral terms, depending upon the current operating parameters. Such operating parameters can include user-selectable parameters, such as heat or airflow settings, and environmental parameters, such as ambient air pressure or temperature.

Other types of controller models may be employed in other implementations. For example, power controller can be based on any combination of proportional, integral or differential parameters. Alternatively, model-based adaptive control may be employed.

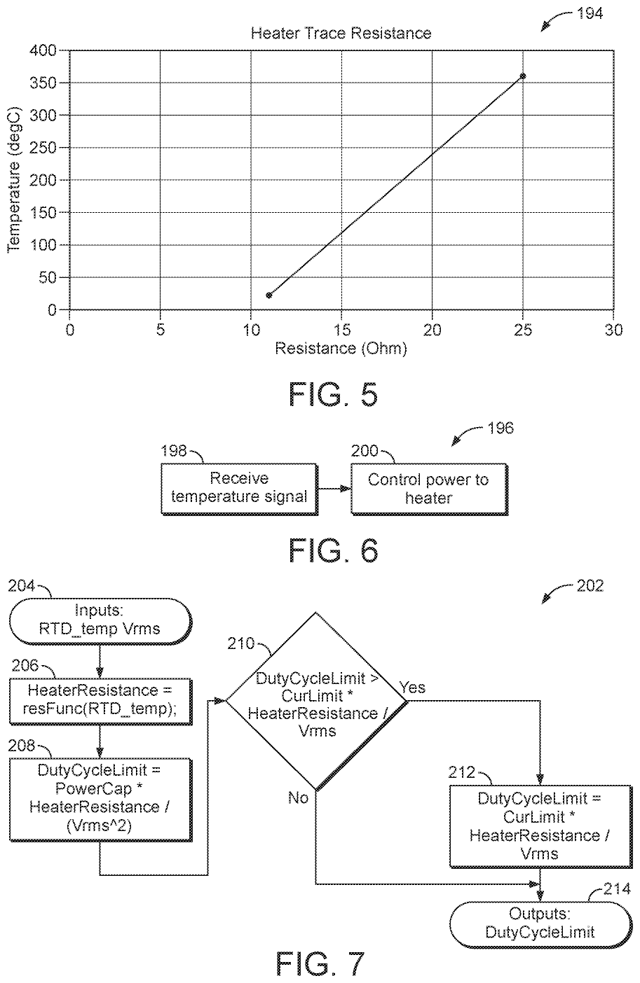

Heater traces 100 of heater 32 may have a positive temperature coefficient. This means that, as the temperature rises, their resistance increases. As shown in graph 194 of FIG. 5, in one example, the resistance (˜11 ohms) at room temperature (˜24° C.) is around half that of the resistance (˜25 ohms) at operating temperature (˜355° C.) This relatively low resistance at turn-on can cause a relatively high inrush current until the resistance rises sufficiently with temperature. High inrush current may damage some of the drive components, or at least reduce their longevity. Also, there may be regulatory issues if the instantaneous power consumption of the appliance exceeds its nominal power rating during this period of high inrush current.

One approach to reducing inrush current is to control an average voltage supplied to heater 32, based on the heater's actual or estimated resistance. Determining a resistance of heater 32 may in practice involve determining some other related characteristic, such as a voltage or a temperature, of the heater or another component, and using that information directly or indirectly. “Indirectly”, in this context, means without expressly converting a characteristic such as voltage or temperature into an actual resistance before use.

Any suitable proxy for heater resistance may be measured and used as a basis for determining or estimating the heater resistance. For example, where the temperature sensor 90 is an RTD, the temperature is determined based on the temperature sensor's relationship between resistance and temperature. The corresponding relationship between RTD and heater trace characteristics can then be used to infer heater resistance, as described in more detail below.

One way of simplifying the temperature/resistance relationship between temperature sensor 90 and heater 32 is to make the temperature sensor 90 out of the same material as the heater trace 100. For example, temperature sensor 90 can be an RTD comprising an additional trace on the same ceramic substrate as that on which the heater traces 100 are formed. If, for example, the same ink is used for both the temperature sensor (i.e., RTD) 90 and heater trace 100, α (the Temperature Coefficient of Resistance (TCR)) will be the same for both. The heater resistance can therefore be inferred from the RTD resistance using the following equations:

$${R}_{RTD} = {R}_{RTD , 25} \cdot ( 1 + α ( {T}_{RTD} - 25 ) )$$

$${R}_{heater} = {R}_{heater , 25} \cdot ( 1 + α ( {T}_{heater} - 25 ) )$$

where R_{heater,25} and R_{RTD,25} are the respective heater and RTD resistances at 25° C.

Since the RTD and heater trace are in close proximity on the same ceramic substrate:

$${T}_{RTD} = {T}_{heater}$$

Then dividing equation \textcircled{2}/\textcircled{1}:

$$\frac{{R}_{heater}}{{R}_{RTD}} = \frac{{R}_{heater , 25}}{{R}_{RTD , 25}}$$

And rearranging:

$${R}_{heater} = \frac{{R}_{heater , 25}}{{R}_{RTD , 25}} \times {R}_{RTD}$$

The skilled person will note that the resultant expression does not include TCR as a variable. Accordingly, if the same ink (or at least a material with similar TCR characteristics) is used for the heater traces and the RTD traces, a variation in TCR will not affect the calculation.

There are also other types of losses, such as wire loss, connector loss, semi-conductor loss, etc, which can optionally be included when considering heater resistance. These losses can be simplified as a function of resistance and combined with the actual heater resistance:

$${R}_{total} = {R}_{heater} + {R}_{loss}$$

$${R}_{total} = [ \frac{{R}_{heater , 25}}{{R}_{RTD , 25}} \times {R}_{RTD} ] + {R}_{loss}$$

The above equation can be simplified to a linear relationship in the form of y=mx+c, where:

$$m = \frac{{R}_{heater , 25}}{{R}_{RTD , 25}} and c = {R}_{loss}$$

R_{heater,25} and R_{RTD,25} are the respective heater and RTD resistances at 25° C; and
Rₗₒₛₛ is a constant that can be determined by modelling and/or testing.

With the relationship between R_{RTD} and Rₕₑₐₜₑᵣ established, it is then straightforward to determine the maximum power, as described in more detail below.

Turning to FIG. 6, there shown a method 196 of controlling power supplied to heater 32. Method 196 comprises repeatedly receiving 198 the temperature signal from heater temperature buffer 94. As explained above, the temperature indicated by the RTD temperature sensor correlates in a known way with the resistance of heater trace 100 (and hence heater 32). It will be appreciated that in other embodiments, a temperature signal may be received from temperature processing circuitry or from the temperature sensor itself. At least partly based on the received temperature signal (which is a proxy for heater resistance), the drive circuitry modulation is controlled such that an average drive voltage supplied to the heater increases as the temperature of the heater increases, and the power supplied to the heater does not exceed a maximum power while the temperature of the heater increases.

Method 196 may, in particular, gradually increase the average voltage supplied to the heater as the temperature of the heater increases during a start-up period of haircare appliance 10. Such a start-up period may begin from the moment when the power is initially supplied to the heater when the haircare appliance 10 is turned on, and may persist for several seconds, for example.

The drive circuitry modulation may also be controlled so as to maximise the power supplied to the heater without exceeding the maximum power. This approach may safely maximise the rate at which the haircare appliance reaches operating temperature.

Controlling the drive circuitry modulation may comprises adjusting a duty cycle of the AC power supply. For example, controlling the drive circuitry modulation may comprise phase angle controlling and/or burst fire controlling the AC power supply, such as by way of TRIAC pattern calculator 74, as described in more detail below. By reducing the effective duty cycle of the AC power supply, the average voltage applied to the heater traces 100 is reduced.

The maximum power may be set or chosen in any suitable way. For example, it can be set as a nominal value that takes into account the nominal power consumption of the haircare appliance and the modelled and/or tested power consumption of its components (other than the heater), optionally including a safety factor. Alternatively, the power consumption of at least some of the components may be estimated and/or measured while the device is in use.

The maximum power can also be chosen with reference to a current limit associated with one or more components of the haircare appliance, and/or the haircare appliance itself. For example, the TRIACs 98 may have a maximum current rating that could be exceeded due to high inrush current at start-up, as a result of the low heater trace resistance. Such a current-based maximum power may be determined by, for example, taking the product of the current limit and the supply voltage.

In the described example, the maximum power is selected as the lesser of that dictated by available power and current limit, both of which are repeatedly calculated and compared during at least a start-up phase of haircare appliance 10.

One particular example of controlling power supplied to heater 32 is shown in FIG. 7, which shows a method 202 performed within current controller 68. Current controller 68 accepts 204 as inputs RTD_temp, which is the temperature signal from heater temperature buffer 94, and Vrms, which is the RMS voltage output by RMS voltage calculator 72 (described in more detail below).

For simplicity, lets represent equation 3 using a resistance function resFunc( ) and Rₜₒₜₐₗ be HeaterResistance. HeaterResistance, is calculated 206 using resistance function, resFunc( ) based on the temperature signal from heater temperature buffer 94.

A duty cycle limit, DutyCycleLimit, having a value between 0 and 1 is initialised 208 as:

$$DutyCycleLimit = PowerCap * HeaterResistance / ( Vrms \hat{} 2 )$$

where PowerCap is a maximum allowable power consumption for the haircare appliance as a whole. In this example, PowerCap is 1700 W, although other maximum allowable power outputs may apply in different applications.

An assessment 210 is then made, to determine whether:

$$DutyCycleLimit > CurLimit * HeaterResistance / Vrms$$

where CurLimit is a maximum allowable current for heater 32. In this example, CurLimit=15 A, although other maximum allowable current limits may apply in different applications.

If the answer to assessment 210 is “yes”, then the value of DutyCycleLimit is updated 212 as follows:

$$DutyCycleLimit = CurLimit * HeaterResistance / Vrms$$

If the answer to assessment 210 is “no”, then the value of DutyCycleLimit is not changed from its initialised value.

Either way, the value of DutyCycleLimit is output 214 to TRIAC pattern calculator 74, which outputs an appropriate pattern as described in more detail below. Method 202 is then repeated as necessary, at least until a threshold temperature (and therefore resistance) for heater 32 is reached. The threshold temperature may optionally be below the maximum operating temperature.

The net effect of method 202 is to ensure that neither a power limit nor a current limit is exceeded during a start-up period, during which heater elements 100 of heater 32 are heated towards their final operating temperature.

An alternative example of controlling power supplied to heater 32 is shown in FIG. 11, which shows a method 302 performed within current controller 68. As with method 204 of FIG. 7, current controller 68 accepts 204 as inputs RTD_temp, which is the temperature signal from heater temperature buffer 94, and Vrms, which is the RMS voltage output by RMS voltage calculator 72 (described in more detail below).

An assessment 324 is made as to whether:

$$PowerCap > CurLimit * Vrms \hat{} 2$$

where PowerCap is a maximum allowable power output for the haircare appliance 10 (or, alternatively, heater 32), and CurLimit is a maximum allowable current associated with one or more components of the haircare appliance 10 (or the haircare device as a whole).

If the answer is no, then the value of a variable HeaterPowerMax is updated 326 as follows:

$$HeaterPowerMax = PowerCap - MotorPower$$

where MotorPower is a constant related to the rated power output of the motor (for each flow mode).

If the answer is yes, then the value of HeaterPowerMax is updated 328 as follows:

$$HeaterPowerMax = ( CurLimit * Vrms ) - MotorPower$$

Next, current heater resistance, HeaterResistance, is calculated 206 using resistance function resFunc( ), as described above in relation to method 202 shown in FIG. 7.

Then, the value of DutyCycleLimit is updated 330 as follows:

$$DutyCycleLimit = HeaterPowerMax * HeaterResistance / Vrms \hat{} 2$$

The value of DutyCycleLimit is output 214 to TRIAC pattern calculator 74. Method 302 is then repeated as necessary, at least until a threshold temperature (and therefore resistance) for heater 32 is reached. The threshold temperature may optionally be below the maximum operating temperature.

The skilled person will appreciate that the main difference between method 302 and method 202 is that the former takes into account power consumed by fan motor 44, which may allow for better overall power control.

Any other suitable method of controlling an average voltage applied to the heater 32 may be employed in order to ensure that a maximum power (and optionally current) is not exceeded as a result of the lower resistance value of the heater trace 100 before it reaches operating temperature.

TRIAC pattern calculator 74 determines what form of TRIAC drive pattern will be used, based on the user-selected target temperature 50 and the duty cycle limit determined by current controller 68 (if a current controller 68 is employed). Any suitable form of TRIAC drive pattern may be used. For example, TRIAC pattern calculator 74 may use a burst-fire control scheme, a phase angle control scheme, or a combination thereof, to control a duty cycle of the AC power supplied to the heater traces 100, and thereby to control the average voltage.

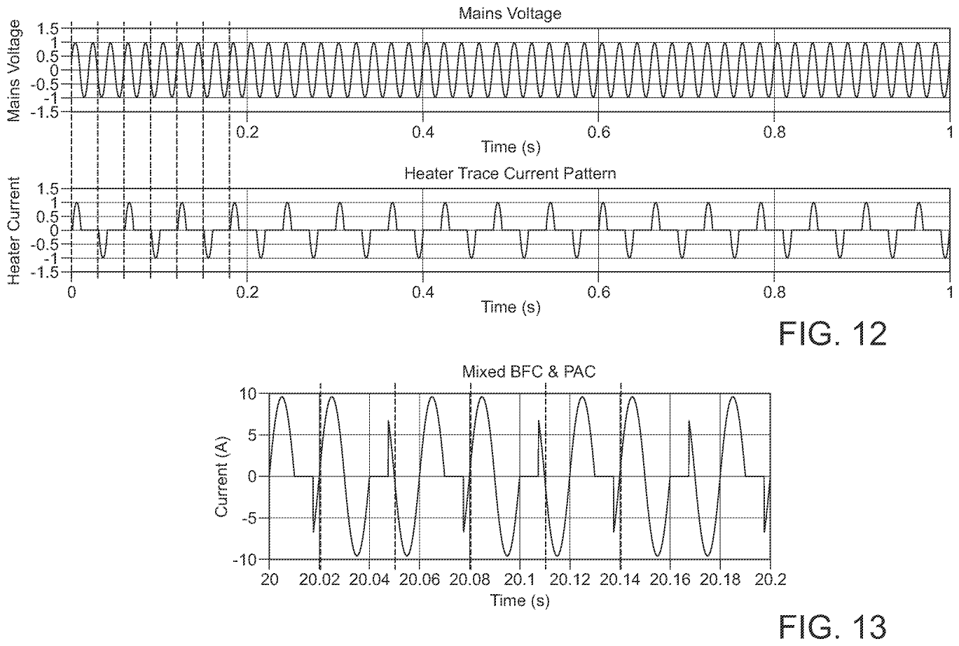

For example, phase angle control may be employed, where the TRIACs are turned on or off at different phase angles. The point at which the TRIACs are turned on/off is selected such that the TRIACs output the required average voltage over the course of each full cycle. Alternatively, as shown in FIG. 12 burst fire may be employed, in which the TRIACs are turned on or off for a sequence of one or more full cycles of the AC power supply. The ratio of on cycles to off cycles determines what proportion of the possible maximum power will be output by the TRIACs over many AC cycles. In FIG. 12, three half cycles are employed as the repetition unit.

A combination of phase angle and burst fire may be employed. For example, the controller may provide a combination of off cycles, on cycles, and phase-angle controlled cycles (or, in each case, half-cycles), such that the required average voltage is output by the TRIACs. For example, and as shown in FIG. 13 a repetitive three half-cycle scheme can be employed, in which one of the half-cycles is phase-angle controlled, and each of the other half cycles is either on or off within each three half-cycle sequence. This provides a useful compromise between control resolution and high-frequency noise, and in particular provides relatively good light “flicker” performance. Other schemes can use different numbers of half-cycles or full-cycles for phase-angle and burst-fire control.

The TRIAC drive pattern generated by TRIAC pattern calculator 74 is provided to TRIAC drive signal generator 76.

TRIAC drive signal generator 76 receives clock signal 250 and the TRIAC pattern from TRIAC pattern calculator 74, and uses them to generate a TRIAC drive signal at an output pin 290 of MCU 48.

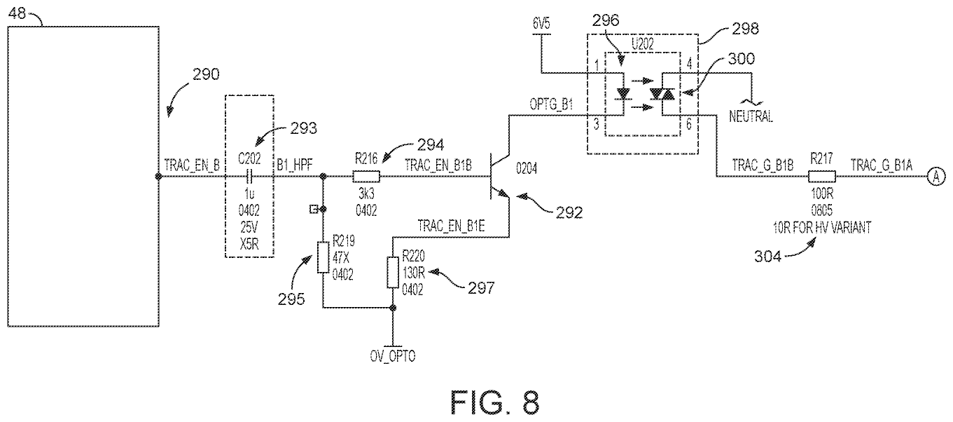

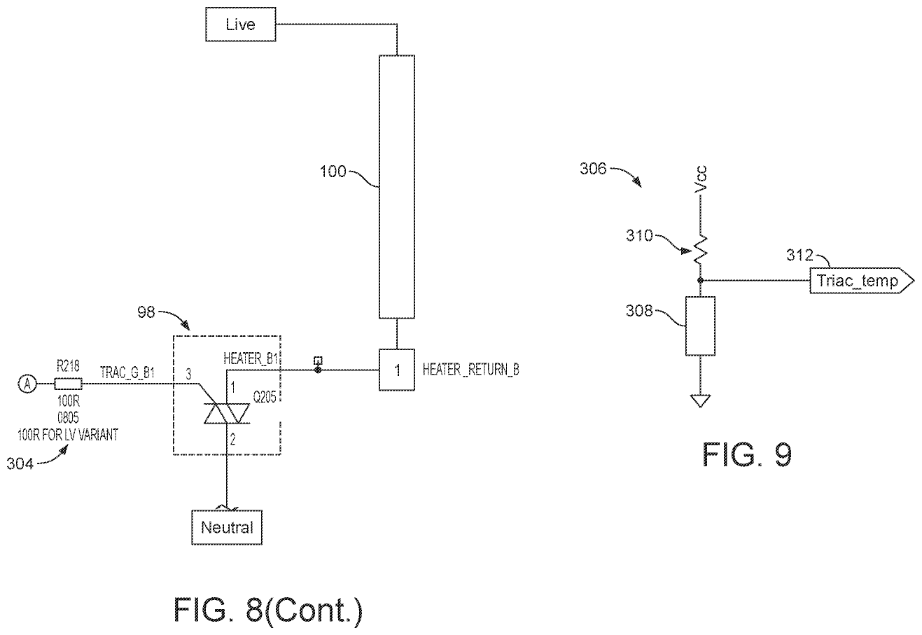

As shown in FIG. 8, the TRIAC drive signal is provided from output pin 290 to the base of a drive transistor 292 via a series-connected capacitor 293 and first resistor 294. A further resistor 295 connects the junction between capacitor 293 and first resistor 294 to 0V. The collector of drive transistor 292 is coupled in series with an LED 296 forming part of an opto-TRIAC 298. The emitter of drive transistor 292 is coupled in series with a current limiting resistor 297. The other terminal of the LED 296 of opto-TRIAC 298 is connected to a power supply (6.5V in this case).

Opto-TRIAC 298 also includes a light-responsive TRIAC 300. One anode of the light-operated TRIAC 300 is coupled to the neutral circuit, and the other anode of light-operated TRIAC 300 is coupled to a gate of power TRIAC 98 (see FIG. 2) via resistors 303. A first anode of power TRIAC 98 is coupled with the neutral circuit and a second anode of power TRIAC 98 is coupled in series with heater trace 100 (see FIG. 2).

When the TRIAC drive signal from output pin 290 is high, drive transistor 292 is turned on, causing current to flow through LED 296 and current limiting resistor 297. Light from LED 296 impinges on light-responsive TRIAC 300, causing it to turn on and connect the neutral circuit to the gate of power TRIAC 98. This causes power TRIAC 98 to start conducting, which in turn allows a drive current to pass through heater trace 100.

When the TRIAC drive signal from output pin 290 is low, drive transistor 292 is turned off, and current does not flow through LED 296. Light-responsive TRIAC 300 therefore remains off, and accordingly no current flows through heater trace 100.

While FIG. 8 only shows the connection of a single opto-TRIAC 298, power TRIAC 98 and heater trace 100, any number of these components may be employed to suit particular implementation requirements. For example, the implementation of FIG. 2 includes three heater traces 100, each of which is driven by a single power TRIAC 98. In other implementations, each power TRIAC 98 can drive one or more heater traces, or each heater trace 100 can be driven by one of more power TRIACs 98, for example.

The optional use of capacitor 293 in series with the base of drive transistor 292 ensures that the power TRIAC 98 is off by default, which may offer additional safety advantages. The capacitor 293 cannot pass DC, and so the TRIAC drive signal is only effective to turn the drive transistor 292 on when it is continuously providing pulses. If output pin 290 remains continuously at a low or high value, the voltage at the base of drive transistor 290 will fall, causing the drive transistor 292 turn off. Accordingly, any software or hardware malfunction that causes a fixed voltage at output pin 290 will not result in spurious activation of heater traces 100.

Although the use of TRIACs is described, any other suitable semiconductor switch or solid state relay may be used, depending upon the implementation. The skilled person will be familiar with any circuitry changes needed in order to allow for devices other than TRIACs to be used as drive components.

Turning to FIG. 9, there is shown a temperature sensing circuit 306. Temperature sensing circuit 306 includes an NTC thermistor 308 connected in series with a pull-up resistor 310. The other terminal of pull-up resistor 310 is connected to a DC voltage Vcc, and the other terminal of NTC thermistor 308 is connected to 0V.

NTC thermistor 308 has a negative temperature coefficient, meaning its resistance decreases as its temperature increases. A voltage taken at the junction between NTC thermistor 308 and pull-up resistor 310 varies in a known manner with temperature, and accordingly can be interpreted as a temperature signal 312. Temperature signal 312 is supplied to MCU 48 for processing, as described below (see also FIG. 2).

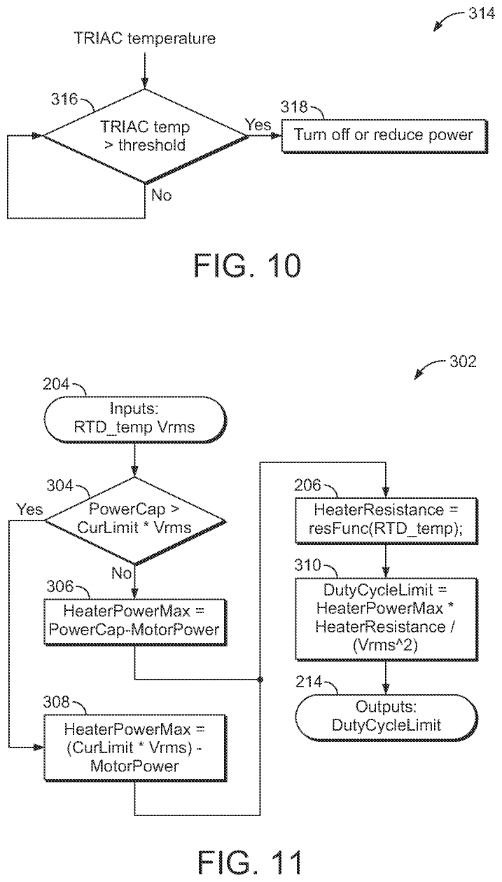

Turning to FIG. 10, there is shown a method 314 performed by MCU 48 in conjunction with temperature sensing circuit 306. First, it is determined 316 whether temperature signal 312 is indicative of a temperature of one or more of the TRIACs 98 exceeding a threshold. This may be by a simple comparison between the current temperature as indicated by temperature signal 312 and a predetermined threshold value stored by MCU 48.

If the outcome of determination 316 is “yes”, MCU 48 turns off or reduces a power output 318 of at least one of the one or more TRIACs 98. If the outcome of determination 316 is “no”, determination 316 is made again. Determination 316 may be repeated at a rate sufficient to provide the desired control of TRIACs 98, such as several times per second.

Optionally, when temperature signal 312 is indicative of the temperature of TRIACs 98 exceeding the threshold, MCU 48 can reduce a power output of the TRIACs until temperature 312 signal is indicative of the temperature of TRIACs 98 beginning to fall. For example, MCU 48 can gradually reduce the power output in a stepwise fashion and monitor whether the temperature of TRIACs 98, as indicated by temperature signal 312, has begun to fall. Once the temperature of TRIACs 98 is falling, MCU 48 can maintain the current power output of the TRIACs 98 and see whether it is sufficient to bring the temperature of the TRIACs below the threshold. If not, MCU 48 can further reduce the power output of the TRIACs, and repeat the process until the temperature of TRIACs 98 is below the threshold.

Once the temperature of TRIACs 98 is below the threshold, MCU 48 can control the power output of the TRIACs 98 to maintain their temperature below the threshold.

MCU 48 may also determine whether the temperature signal 312 is indicative of a temperature of the TRIACs 98 exceeding a further threshold, and immediately turn off power to the TRIACs 98 if the further threshold is exceeded. For example, the further threshold may be selected such that it indicates potential thermal runaway of TRIACs 98, in which case TRIACs 98 are immediately shut down.

MCU 48 may also determine a rate of change of temperature signal 312, especially as it approaches or exceeds a threshold below that indicating a thermal runaway condition. For example, a higher than expected rate of change may be indicative of a problem, even before the further threshold is reached. In that case, it is beneficial to immediately shut down TRIACs 98.

Thermistor 308 can be mounted in contact with, or closely adjacent to, at least one of the TRIACs 98. This reduces lag compared to having the thermistor 308 mounted more remotely. For example, thermistor 308 can be mounted to the same PCB (not shown) as TRIACs 98.

Thermistor 308 can be mounted within a cavity of the haircare appliance 10, at least a portion of the TRIACs 98 (or at least one of the TRIACs 98) extending into, or being in contact with a wall of, the cavity, such that the thermistor is arranged to sense the temperature of the TRIACs 98 indirectly by sensing the temperature of the air within, or the wall of, the cavity.

Optionally, thermistor 308 and one or more of TRIACs 98 can be potted with a potting compound. For example, all of TRIACs 98 can be potted with thermistor 308 within a single block of potting compound. The potting compound helps physically protect the TRIACs and reduce the chance of them shorting. Further, heat from the TRIACs is distributed through the potting compound, which may assist in correlating thermistor temperature with overall TRIAC temperatures.

Although the haircare appliance 10 shown in FIGS. 1-3 uses only a single thermistor 308, it is also possible to use multiple thermistors, or other temperature sensors, to sense the temperature of the TRIACs. For example, each TRIAC 98 can have its own thermistor 308, or other temperature sensor. This provides greater accuracy at the expense of cost and complication.

Although not shown in FIG. 2, circuitry housing 12 can also include a voltage sensing circuit similar to voltage sensing circuit 70, and a further microprocessor, for sensing AC mains supply voltage at the circuitry housing. The sensed voltage can be used, for example, to prevent the haircare appliance from turning on if the voltage is outside an acceptable range. Alternatively, or in addition, the voltage can be monitored for temporary power loss, such as in a brown-out or similar situation. If, in use, the voltage drops below a critical level for more than some predetermined period, operation of the haircare appliance 10 may be halted for safety. An example period would be 20 ms, although other periods may be selected based on circumstances.

More generally, the skilled person will appreciate that there may be a different distribution of components between circuitry housing 12 and heater housing 14 than that shown. Optionally, circuitry housing 12 can incorporate power connector (i.e., plug) 15, such that circuitry housing 12 can be directly plugged into a power socket. Alternatively, all of the components may be disposed within a heater housing, without the use of a separate circuitry housing such as circuitry housing 12.

The hair care appliance may implement various temperature-related safety functions. Such functions can provide an escalating series of responses that are proportionate to the circumstances. For example, a transient increase in air exit temperature may represent a brief covering of the air inlet or outlet, and therefore complete and/or permanent shutdown may not be warranted. On the other hand, sustained overheating of the heater may indicate a more significant hardware problem, as well as presenting a potentially greater risk of damage to the device if the heater continues to be driven at the current level.

One way of providing an escalating series of responses is to control a driving circuit (e.g., opto-TRIACS 298 and TRIACs 98) responsive to a temperature associated with one or more components of the hair care appliance, and/or an airflow through airflow path 102. The one or more components can include, for example, heater 32 and/or TRIACs 98.

Temperatures can be sensed as described above, and the temperature provided as either a temperature value or a signal indicative of the sensed temperature. The temperature value or signal is then provided to MCU 48 as described, as well as to a hardware circuit in the form of overheat protection circuitry 96.

Software running on MCU 48 determines, based on the received temperature value or temperature signal, whether a first temperature threshold has been exceeded. For example, the first temperature threshold may relate to the AET temperature representative of the temperature of the airflow as it exits airflow path 102. Alternatively, the first temperature threshold may relate to the temperature of heater 32 as sensed by heater temperature sensor 90.

In parallel, overheat protection circuitry 96 determines, based on the received temperature value or temperature signal, whether a second temperature threshold has been exceeded. The second temperature threshold may relate to the same component or airflow path to which the first temperature threshold is applied by MCU 48.

When the first temperature threshold and/or the second temperature threshold has been exceeded, the TRIACS can be controlled to reduce or halt drive to the heater. For example, where a low-power semiconductor switch such as opto-TRIAC 298 is used to drive a high-power semiconductor switch such as TRIAC 98, the TRIAC drive signal provided from output pin 290 (see FIG. 8) can be changed or stopped, thereby correspondingly reducing the power output by TRIACs 98.

Where the first and second temperature threshold relate to the same component or airflow path, the second threshold may be set to a higher value than the first threshold. This results in the first threshold being reached earlier as a result of a rising temperature, which causes the reduction or halting of drive to heater 32 to be controlled by the software running on MCU 48 before the overheat protection circuitry 96 becomes involved. This offers the advantage of more flexibility in how the drive to heater 32 is controlled, as well as potentially simpler resetting of the drive to heater 32.

Alternatively, or in addition, a delay may be applied to an input and/or an output of overheat protection circuitry 96. If the sensed temperature is rising, then delaying input of the sensed temperature to overheat protection circuitry 96, or delaying the control output, will increase a likelihood of the first temperature threshold being exceeded, or at least acted upon, before the second temperature threshold is exceeded or acted upon.

The delay may be a simple time delay, for example. Alternatively, or in addition, the input or output to overheat protection circuitry 96 can be filtered. For example, applying a low pass filter introduces a lag, which effectively delays the second threshold being reached relative to the first threshold. As such, even if the first and second thresholds are the same, such filtering increases a likelihood of the first temperature threshold being exceeded, or at least acted upon, before the second temperature threshold is exceeded or acted upon. The skilled person will appreciate, however, that the first and second temperature threshold need not be the same.

Temperatures of more than one of the components and/or the airflow can simultaneously or sequentially be sensed. For example, the AET temperature and heater temperature can be sensed, and different thresholds applied to them by both the MCU 48 and overheat protection circuitry 96.

Following reduction or halting of drive to heater 32 following passing of a threshold, it may be possible to reset or otherwise control the drive to heater 32.

For example, the drive to heater 32 may automatically be increased or restored based on further sensed temperatures. For example, if the temperature of whichever component caused a threshold to be exceeded falls back below the threshold, optionally for some predetermined period of time, then the drive to heater 32 may be restored. Restoring of the drive may be gradual, or instantaneous, and may optionally be controlled based on ongoing temperature sensing.

Hysteresis may be employed such that the temperature will need to fall below the exceeded threshold by some amount, and/or for some period of time, before the drive is restored (or is allowed to be restored, where further user or technician action is required).

The drive to heater 32 may alternatively be increased or restored only after specific user input. For example, the crossing of one of the thresholds may cause user feedback, such as audible feedback, tactile feedback (e.g., vibration or pulsing, optionally caused by the fan motor), or visual feedback through the use of, for example, one or more indicators forming part of the user interface. The user may be guided to perform a function, such as holding down a button for a period of time, or cycling power to the haircare appliance.

Optionally, drive to heater 32 may be restored only by a suitably qualified and equipped technician, rather than being under the control of the user.

Where multiple thresholds for different components and/or the airflow pathway are in use, any or all of the above approaches to restoring drive to heater 32 may be employed in combination.

For example, where a lower threshold is exceeded, it may be sufficient to reduce drive to heater 32, with the drive automatically being restored once the temperature reduces sufficiently. Where an intermediate threshold is exceeded, it may be necessary to halt drive to heater 32, and to require power cycling of haircare appliance 10 to restore the drive (assuming the temperature falls sufficiently). Where a further threshold is exceeded, indicating a potentially significant fault, a non-resettable protection may be triggered, requiring intervention of a technician.

An example of a multi-layered approach to heating and overheating control is set out in the following table:

| | | |
|---|---|---|
| Software | Layer 1 | Temperature PI control (for both AET and heater) |
| | Layer 2 | AET overheat protection |
| | Layer 3 | Heater overheat protection |
| Hardware | Layer 4 | AET overheat resettable protection |
| | Layer 5 | Heater overheat non-resettable protection |

Layer 1 involves ordinary heating control as described previously, where no overheating is detected.

Layer 2 applies when a temperature threshold for AET temperature is reached or exceeded, as determined by software running on MCU 48. This threshold may be, for example, an AET temperature of 200° C. Once this threshold is exceeded, the protection circuit will disable the TRIAC drive signals to turn off opto-TRIAC 298, and hence TRIAC 98. The TRIAC drive signals can subsequently be re-enabled in any suitable manner. For example, the user can power cycle appliance 10, and as long as the AET temperature is below 200° C., the heating control will return to layer 1. Alternatively, the TRIAC signal can automatically be re-enabled when the AET temperature decreases to a particular temperature (such as 50° C., for example) even without a power cycle.

Layer 3 applies when a temperature threshold for heater 32 is reached or exceeded, as determined by software running on MCU 48. This threshold may be, for example, a heater temperature exceeding 437.5° C. Once this threshold is exceeded, relay 46 is opened, removing the power supply to TRIACs 98. Relay 47 can subsequently be closed in any suitable manner. For example, the user can power cycle appliance 10, and as long as the heater temperature is below 437.5° C., the heater control will return to layer 1. Alternatively, or in addition, the relay can be closed when the heater temperature decreases to a particular temperature (such as 50° C., for example), even without a power cycle.

Layer 4 applies when a further temperature threshold for AET temperature is reached or exceeded, as determined by overheat protection circuitry 96. This threshold may be, for example, an AET temperature of 200° C. However, by applying a low pass filter to the temperature signal, this temperature threshold will be reached by overheat protection circuitry 96 later than by software on MCU 48. As such, the layer 4 protection will ordinarily only be triggered if there is some form of hardware or software failure that causes the hardware threshold to be reached before the software threshold.

Layer 5 applies when a further temperature threshold for heater 32 is reached or exceeded, as determined by overheat protection circuitry 96. This threshold may be, for example, a heater temperature exceeding 437.5° C. However, by applying a low pass filter to the temperature signal, this temperature threshold will be reached by overheat protection circuitry 96 later than by software on MCU 48. As such, the layer 5 protection will ordinarily only be triggered if there is some form of hardware or software failure that causes the hardware threshold to be reached before the software threshold.

Triggering of layer 5 protection suggests a significant hardware or software failure, to the point where it may be preferable to prevent the device being reset automatically or by a user. Accordingly, once layer 5 protections are triggered, drive to heater 32 may be restored only by a suitably qualified and equipped technician, rather than being under the control of the user.

The skilled person will appreciate that the above is just one example of how a multi-layered approach may be implemented. Different components, thresholds, filtering, hysteresis parameters, numbers of layers, and various combinations thereof, may be selected depending upon the specific functional (and in some jurisdictions, legal) requirements for overheat protection.

Although thresholds have been described with reference to temperature values, it will be appreciated that any or all thresholds may also have an associated time threshold. For example, a first threshold can be triggered only if the temperature exceeds a temperature threshold for a time threshold (e.g., 200° C. for three seconds), and a second threshold can be triggered only if the temperature exceeds a different temperature for a different time threshold (e.g., 210° C. for one second).

Temperatures of other components or areas of haircare appliance may also be monitored. For example, a temperature of one or more components within fan motor controller may be monitored. If a threshold temperature is exceeded, then an action can be taken to reduce the temperature. For example, the speed of fan motor can be reduced. If that does not work (or work quickly enough), the haircare appliance fan motor can be turned off, and/or the haircare appliance can be placed into “standby” or “off” mode where the fan does not run. The user may be notified of the overheating by way of feedback such as audible, visual, or tactile feedback such as that described above. The fan motor controller can restart when the temperature has dropped sufficiently, optionally taking into account a hysteresis value.

While haircare appliance 10 has been described as a hairdryer, it will be appreciated that many of the teachings discussed herein may be applied to other types of haircare appliance, such as hair straighteners, hair curlers, and the like, for example.

1. A haircare device comprising:
a heater;
at least one power semiconductor switch coupled to drive, in use, the heater;
a temperature sensor disposed for sensing a temperature of the at least one power semiconductor switch and outputting a temperature signal indicative of the sensed temperature; and
a controller coupled to control the at least one power semiconductor switch and to receive the temperature signal from the temperature sensor, the controller being configured to:
determine whether the temperature signal is indicative of a temperature of the one or more power semiconductor switch exceeding a threshold; and
when the temperature signal is indicative of the temperature of the one or more power semiconductor switch exceeding the threshold, turn off or reduce a power output of the at least one power semiconductor switch.

2. The haircare device of claim 1, comprising an airflow path, the airflow path having disposed within it:
an airflow generator for moving air downstream through the airflow path; and
the heater.

3. The haircare device of claim 2, wherein at least a portion of the at least one power semiconductor switch is in contact with air flowing through the air flow path, thereby to cool the at least one power semiconductor switch when the haircare device is in use.

4. The haircare device of claim 1, wherein the controller is configured to, when the temperature signal is indicative of the temperature of the at least one power semiconductor switch exceeding the threshold, reduce a power output of the at least one power semiconductor switch until the temperature signal is indicative of the temperature of the at least one power semiconductor switch beginning to fall.

5. The haircare device of claim 4, wherein the controller is configured to keep the power output of the at least one power semiconductor switch reduced until the temperature signal is indicative of the temperature of the at least one power semiconductor falling below the threshold.

6. The haircare device of claim 4, wherein the controller is configured to, after the temperature signal is indicative of the temperature of the at least one power semiconductor falling below the threshold, control the power output of the at least one power semiconductor switch to maintain the temperature of the at least one power semiconductor below the threshold.

7. The haircare device of claim 1, wherein the controller is configured to:
determine whether the temperature signal is indicative of a temperature of the one or more power semiconductor switches exceeding a further threshold; and
when the temperature signal is indicative of the temperature of the one or more power semiconductor switches exceeding the further threshold, turn off the at least one power semiconductor switch.

8. The haircare device of claim 1, wherein the at least one power semiconductor switch comprises at least one TRIAC.

9. The haircare device of claim 1, wherein the temperature sensor is mounted in contact with at least one of the at least one power semiconductor switch.

10. The haircare device of claim 1, wherein the temperature sensor is mounted within a cavity of the haircare device, at least a portion of the at least one power semiconductor switch extending into, or being in contact with a wall of, the cavity, such that the temperature sensor is arranged to sense the temperature of the at least one power semiconductor switch indirectly by sensing the temperature of the air within, or the wall of, the cavity.

11. A method performed by a haircare device comprising:
a heater;
at least one power semiconductor switch coupled to drive, in use, the heater; and
a temperature sensor disposed for sensing a temperature of the one or more power semiconductor switches and outputting a temperature signal indicative of the sensed temperature;
the method comprising:
receiving the temperature signal from the temperature sensor;
determining whether the temperature signal is indicative of a temperature of the one or more power semiconductor switches exceeding a threshold; and
when the temperature signal is indicative of the temperature of the one or more power semiconductor switches exceeding the threshold, turning off or reducing a power output of the at least one power semiconductor switch.

12. A haircare appliance comprising:
a processor having a first input;
a temperature processing circuit separate to the processor, the temperature processing circuit having a second input;
a temperature sensor for sensing a temperature within the haircare appliance and outputting a temperature signal indicative of the sensed temperature, the temperature signal being supplied, in use, to the first and second inputs in parallel; and
a buffer disposed in series between:
the first input; and
the second input and the temperature sensor;
the buffer preventing or mitigating an effect on the second output of a signal generated on the first input.

13. A method of operating a haircare appliance, comprising:
generating a temperature signal indicative of a temperature associated with a portion or region of the haircare appliance; and
supplying the temperature signal, in parallel, to:
a first input of a processor via a buffer; and
a second input of a temperature processing circuit separate to the processor;
the buffer preventing or mitigating an effect on the second output of a signal generated on the first input.

14-15. (canceled)

16. A method of controlling power supplied to a heater disposed within an airflow path of a haircare appliance, the heater being coupled to be driven by an AC power supply modulated by drive circuitry, the method comprising repeatedly:
determining a resistance of the heater;
based on the determined resistance, controlling the drive circuitry modulation such that:
an average drive voltage supplied to the heater increases as the temperature of the heater increases; and
the power supplied to the heater does not exceed a maximum power while the temperature of the heater increases.

17. A haircare appliance comprising:
a heater disposed within an airflow path of a haircare appliance;
a sensor mounted with or adjacent to the heater, and configured to generate a signal indicative of a resistance of the heater;
drive circuitry coupled to modulate an AC power supply for driving the heater; and
a controller configured to:
receive the signal;
determine, based on the signal, a control signal for controlling the drive circuitry; and
output the control signal to control the drive circuitry modulation;
such that:
an average drive voltage supplied to the heater increases as the temperature of the heater increases; and
the power supplied to the heater does not exceed a maximum power while the temperature of the heater increases.

18-19. (canceled)
